(19) United States
(12) Patent Application Publication
(10) Pub. No.: US 2026/0344428 A1
(43) Pub. Date: Oct. 29, 2026

(54) Optical Transmitter

(71) Applicant: NTT, Inc., Tokyo (JP)

(72) Inventors: Josuke Ozaki, Musashino-shi, Tokyo (JP); Yoshihiro Ogiso, Musashino-shi, Tokyo (JP); Mitsuteru Ishikawa, Musashino-shi, Tokyo (JP)

(21) Appl. No.: 19/117,926

(22) PCT Filed: Oct. 3, 2022
(86) PCT No.: PCT/JP2022/037033

§ 371 Date: Apr. 2, 2025

(51) Int. Cl. H10W 40/28; G02B 6/42; H04B 10/50; H10W 40/20; H10W 72/30; H10W 90/00; H10W 90/10

(52) U.S. Cl. CPC H10W 40/28; G02B 6/4206; G02B 6/4271; H04B 10/501; H10W 40/242; H10W 72/365; H10W 90/10; H10W 90/732

(57) ABSTRACT

There is provided a novel configuration and mounting form of an optical transmitter that suppresses temperature dependency of optical modulation output characteristics and has excellent speed. An optical transmitter according to the present disclosure includes an optical modulator chip, a driver IC for operating the optical modulator chip, a wiring board that has a substantially linear high frequency line, connects the optical modulator chip and the driver IC, and is face-down mounted by flip-chip mounting, and a Peltier device mounted below the optical modulator chip and the driver IC, in which the optical modulator chip and the driver IC are temperature-controlled by the Peltier device that is the same.

### TECHNICAL FIELD

The present disclosure relates to an optical transmitter used in optical communication. More particularly, the present disclosure relates to a mounting form of an optical transmitter including a semiconductor optical modulator and a driver IC thereof.

### BACKGROUND ART

In order to respond to a rapid traffic increase of a communication network, digital coherent optical transmission combining a coherent communication method and a digital signal processing technology has been introduced into an optical fiber communication system. Starting from the establishment of a backbone network transmission technology of 100 Gbps per wavelength at the beginning, transmission of 400 to 600 Gbps per wavelength, which is faster, has been put into practical use at present.

In the above-described digital coherent optical transmission, an optical transmission-reception device in which an optical receiver and an optical transmitter are integrated is used. In an optical transmission-reception device of a system having a transmission capacity exceeding 400 Gbps, an analog component such as a high frequency (RF) electric circuit is required to have a wider bandwidth, and for example, in an optical modulator, a modulation bandwidth of 40 GHz or more is necessary. For reduction of high frequency loss and downsizing of a device, which are linked to a wider bandwidth, for example, a form in which an RF driver IC and an optical modulator are mounted in an integrated package on the transmission side has attracted attention. A mounting form of the optical transmitter is also standardized by the Optical Internetworking Forum (OIF) under the name of High-Bandwidth Coherent Driver Modulator (HB-CDM) (Non Patent Literature 1). Also on the reception side of the optical transmission-reception device, a transimpedance amplifier (TIA) and an optical receiver are mounted in an integrated package, and is also referred to as an integrated coherent receiver (ICR).

Turning to materials for optical transmitting and receiving devices, semiconductor-based optical modulators have attracted attention instead of conventional lithium niobate (LN) optical modulators from the viewpoint of miniaturization and cost reduction. For higher-speed modulation operation, a compound semiconductor represented by InP is mainly used. In addition, research and development are concentrated on Si-based optical devices in systems in which more miniaturization and cost reduction are regarded as important.

There are advantages and disadvantages inherent to the materials also in the above-described semiconductor optical modulator, and for example, in an InP optical modulator, temperature control of an optical modulator chip is essential duringoperation in order to control a band edge absorption effect. On the other hand, the Si optical modulator has a merit that temperature control is unnecessary, but has a smaller electro-optical effect than other material systems. For this reason, it is necessary to increase the electro-optical interaction length, and as a result of increasing the device length, a high frequency loss may be increased. There are many problems in further increasing the speed and bandwidth of the optical modulator including a mounting technology for increasing the bandwidth and reducing the size.

The operation temperature (case temperature) of the optical transmitter based on the HB-CDM is required to be in a range of at least −5 °C to 75 °C. In order to ensure such an operation temperature, generally, only an optical modulator chip is mounted on a Peltier device in consideration of power consumption (Patent Literature 1).

However, in the optical transmitter of the related art, deterioration of high frequency characteristics of the driver IC at high temperature has been a problem. Specifically, in a case where the environmental temperature is in a high temperature state, there has been a problem that the high frequency band, the peaking amount, and the gain of the driver IC are deteriorated. As optical transmitters have increased in speed and bandwidth, the influence of deterioration in signal quality due to the above-described deterioration cannot be ignored. Thus, an optical transmitter capable of maintaining a constant high frequency characteristic regardless of a change in environmental temperature is desired.

### CITATION LIST

### Patent Literature

Patent Literature 1: WO 2021/171599 A1

### Non Patent Literature

Non Patent Literature 1: OIF, Implementation Agreement for the High Bandwidth Coherent Driver Modulator (HB-CDM), [online], Jul. 15, 2021, [Searched on Sep. 1, 2022], the Internet <URL: https://www.oiforum.com/wp-content/uploads/OIF-HB-CDM-02.0.pdf>

Non Patent Literature 2: J. Ozaki et al., “500-Gb/s/λ Operation of Ultra-Low Power and Low-Temperature-Dependence InP-Based High-Bandwidth Coherent Driver Modulator,” in Journal of Lightwave Technology, vol. 38, no. 18, pp. 5086-5091, 15Sept. 15 , 2020, doi: 10.1109/JLT.2020.2998466.

### SUMMARY OF INVENTION

In view of the above problems, the present invention provides a novel configuration and mounting form of an optical transmitter that can suppress temperature dependency of an optical transmitter including a driver IC, has excellent speed, and can stably operate regardless of environmental temperature.

In order to solve the problem as described above, the present disclosure provides an optical transmitter including an optical modulator chip, a driver IC for operating the optical modulator chip, a wiring board that has a substantially linear high frequency line, connects the optical modulator chip and the driver IC, and is face-down mounted by flip-chip mounting, and a Peltier device mounted below the optical modulator chip and the driver IC, in which the optical modulator chip and the driver IC are temperature-controlled by the Peltier device that is the same.

### BRIEF DESCRIPTION OF DRAWINGS

FIG. 1 is a side cross-sectional view illustrating a mounting form of an optical transmitter 100 according to HB-CDM of a related art.

FIG. 2 is a side cross-sectional view illustrating a mounting form of an optical transmitter 200 according to the present disclosure.

FIG. 3 is a side cross-sectional view illustrating a mounting form of an optical transmitter 300 according to the present disclosure.

FIG. 4 is a side cross-sectional view illustrating a mounting form of an optical transmitter 400 according to the present disclosure.

FIG. 5 is a side cross-sectional view illustrating a mounting form of an optical transmitter 500 according to the present disclosure.

FIG. 6 is a side cross-sectional view illustrating a mounting form of an optical transmitter 600 according to the present disclosure.

FIG. 7 is a side cross-sectional view illustrating a mounting form of an optical transmitter 700 according to the present disclosure.

FIG. 8 is a diagram illustrating a configuration of a Peltier device 205 used in an optical transmitters 200 to 700 according to the present disclosure.

### DESCRIPTION OF EMBODIMENTS

Hereinafter, various embodiments of the present disclosure will be described in detail with reference to the drawings. The same or similar reference signs denote the same or similar components, and redundant description will be omitted in some cases. The materials and numerical values are for illustrative purposes and are not intended to limit the scope of the disclosure. The following description is an example, and some configurations may be omitted, modified, or implemented together with additional configurations without departing from the gist of an embodiment of the present disclosure.

The present disclosure presents a new configuration for improving temperature dependency of a high frequency characteristic of an optical transmitter in an optical transmitter in which an optical modulator and a driver IC thereof are integrally packaged, and a mounting form adapted to each configuration. The configuration for improving the temperature dependency includes a new application form of a temperature regulator (thermoelectric cooler (TEC)) in the optical transmitter. In addition, various mounting forms of driver ICs, optical modulator chips, and spatial optical components adapted to new applications of TECs are also proposed.

The TEC is also called a thermoelectric cooler, and is known as a small cooling device by Peltier junction. The TEC is constituted by an n-type semiconductor, a p-type semiconductor, and a metal, and when a direct current flows on both surfaces of an element formed in a plate shape, heat absorption occurs on one surface and heat dissipation occurs on the other surface. When the direction of the current is reversed, heat absorption and heat dissipation are switched, so that local and accurate temperature control of the IC and the electronic component is possible. In the following description, the temperature regulator is referred to as a TEC for simplicity, and will be described as a Peltier device. As long as the temperature of the driver IC or the optical modulator chip can be controlled, the present invention is not limited to the Peltier device.

In the following, the problem of the temperature dependency of the high frequency characteristics in the optical transmitter will be first described by using an optical modulator in the form of the HB-CDM of the related art as an example. Thereafter, a novel configuration for improving the temperature dependency of the high frequency characteristics by the optical transmitter of the present invention will be described together with various mounting forms.

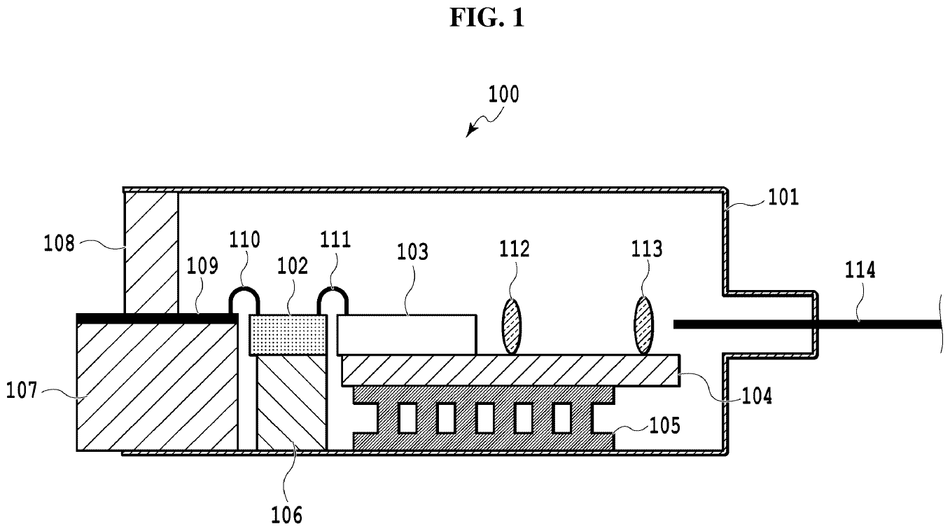

FIG. 1 is a side cross-sectional view illustrating a mounting form of an optical transmitter based on the HB-CDM of the related art. In the optical transmitter 100, a driver IC 102, an optical modulator chip 103, lenses 112 and 113 which are spatial optical components, and the like are housed inside a package housing 101 made by ceramic and the like according to the specification of the HB-CDM. More specifically, the optical modulator chip 103 is mounted on a bottom surface inside the housing 101 via the subcarrier 104 on the Peltier device 105. At the right end of the optical modulator chip 103 in the drawing, there is an emission end surface of modulated light, and lenses 112 and 113 for optically coupling the modulated light with the optical fiber 114 are also mounted on the subcarrier.

The driver IC 102 is mounted on the metal block or a ceramic material 106 adjacent to the optical modulator chip 103. Further, a wiring board base 107 and a package wall surface 108 are provided as wall surfaces on the left side in the drawing of the package housing 101, and partition the outside and an internal space of the optical transmitter together with the package housing 101. The optical transmitter 100 can be configured in such a manner that the entire package ensures airtightness.

A modulated electrical signal supplied from an external digital signal processor (DSP) is supplied to the optical modulator chip 103 via the wiring layer 109 of the wiring board base 107 and the driver IC 102. The wiring layer 109 and the driver IC 102, and the driver IC 102 and the optical modulator chip 103 are connected by gold wire lines 110 and 111, respectively. In the case of the polarization multiplexing type IQ optical modulation method, the modulated electrical signal includes an I channel and a Q channel for each of the X polarized wave and the Y polarized wave. When one channel is supplied as an electrical signal in a differential signal form, at least eight signal wirings and a GND wiring are necessary for one optical modulator, but the modulation signal form is not limited thereto. As illustrated in Patent Literature 1, the optical modulator 100 illustrated in FIG. 1 is mounted on a common device substrate together with an ICR package or a DSP in which a TIA and an optical receiver on the reception side are integrated, and can constitute an optical transmission-reception device.

Here, attention is again focused on the Peltier device 105 in the optical transmitter. Temperature control is essential in the optical modulator chip 103 manufactured on the InP substrate, and is controlled to a predetermined operation temperature by the Peltier device 105. As illustrated in FIG. 1, the Peltier device 105 has a size that covers at least the entire region of the optical modulator chip 103, and its position may overlap a region of a spatial optical component such as a lens. On the other hand, in the optical transmitter 100 of the related art, it is considered that the temperature control of the driver IC 102 is not necessary, and the optical transmitter is fixed in the package by the member 106 such as a metal block or ceramic. When the external temperature (environmental temperature) of the optical transmitter 100 rises, the raised temperature becomes the operation temperature of the driver IC 102. When the maximum environmental temperature at which the optical transmission-reception device including the optical transmitter is used is 85 °C, the temperature of the driver IC 102 itself is at least 85 °C or higher. The driver IC also has large power consumption, and the driver IC itself generates heat. Therefore, this means that the back side temperature of the driver IC exceeds the maximum environmental temperature of 85 °C due to the influence of heat generation of the driver IC.

The driver IC has temperature dependency on an amplification characteristic (high frequency characteristic) of a high frequency electrical signal, and in a high temperature state, a high frequency band tends to be lower than that in a room temperature state. Conversely, in the low temperature state, the high frequency band tends to increase as compared with the room temperature state. As described above, the high frequency characteristics of the driver IC are different between the low temperature state and the high temperature state. A modulation signal supplied to the driver IC is variously optimized and compensated by the DSP in a room temperature state. However, performing such compensation while dynamically updating with temperature variation is a complicated process and is not generally performed. Since the operation is continued in a constant compensation state at room temperature, the compensation state of the modulation signal deviates from an optimum point when the state changes to the low temperature state or the high temperature state. Thus, optical transmission characteristics and waveform quality of the optical transmitter fluctuate or deteriorate.

The IQ modulator of the optical modulator chip 103 is a linear modulator that preserves the amplitude and phase of the electrical signal, and variations in the level and waveform quality of the modulated electrical signal directly affect the quality of the modulated output light. When the external temperature changes during the operation of the optical transmitter, the operation temperature of the driver IC changes although the optical modulator chip itself is maintained at a constant temperature because the temperature is managed by the Peltier device.

As a result, a level variation and a quality variation of the modulated light of the HB-CDM occur, and a transmission characteristic is deteriorated and a problem that the transmission characteristic is not stable also occurs due to a temporal change in the environmental temperature.

The characteristic deterioration caused by the environmental temperature on the high-frequency side of the electrical signal causes waveform distortion of the modulation signal, and the modulation accuracy of the modulated output light from the optical modulator is deteriorated. In an optical receiver that receives such deteriorated modulated light, a BER characteristic has a floor, which leads to deterioration of a transmission characteristic of a system.

The influence of degradation of the high frequency characteristics of the driver IC at high temperatures as described above cannot be ignored in a situation in which a modulation band of 40 GHz or more is required as a demand for widening the bandwidth of the modulated electrical signal advances. The present invention presents a new configuration and mounting form that improve temperature dependency in high frequency characteristics and optical transmission characteristics in an optical transmitter in which an optical modulator and a driver IC thereof are integrally packaged.

An optical transmitter according to an embodiment of the present disclosure will be described in detail below with reference to the drawings. It should be noted that, in the following description, the optical transmitter according to the present disclosure is described as a form of a HB-CDM of a flexible printed circuit board (FPC) interface. However, this is for the purpose of illustration, and an optical transmission module in which a driver IC and an optical modulator chip are integrated has a similar effect.

### Overall Configuration

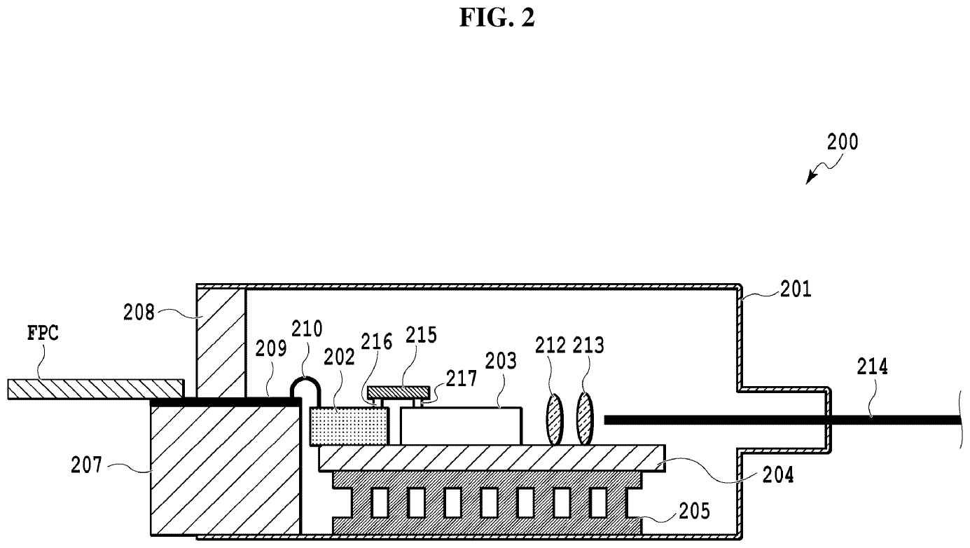

FIG. 2 is a side cross-sectional view illustrating a mounting form of an optical transmitter 200 according to the present disclosure. As illustrated in FIG. 2, in the optical transmitter 200, a driver IC 202, an optical modulator chip 203, an optical member (in FIG. 2, lenses 212 and 213, which are spatial optical components, are depicted as an example), and the like are housed inside a package housing 201. More specifically, the optical modulator chip 203 is mounted on the bottom surface inside the housing 201 via a subcarrier 204 on the Peltier device 205. At the right end of the optical modulator chip 203 in the drawing, there is an emission end surface of modulated light, and the lenses 212 and 213 for optically coupling the modulated light with the optical fiber 214 are also mounted on the subcarrier.

Further, the optical transmitter 200 includes a wiring board base 207 and a package wall surface 208 as left wall surfaces of the package housing 201 in the drawing, and defines the outside and an internal space of the optical transmitter together with the package housing 201. Furthermore, the wiring board base 207 includes a package terrace, and a wiring layer 209 formed on the upper surface of the package terrace is connected to a flexible substrate (FPC) as a high-frequency interface. Note that the optical transmitter 200 can also be configured in such a manner that the entire package ensures airtightness.

A modulated electrical signal supplied from an external digital signal processor (DSP) is supplied to the optical modulator chip 203 via the wiring layer 209 of the wiring board base 207 and the driver IC 202. The wiring layer 209 and the driver IC 202 are connected by a gold wire line 210. On the other hand, the driver IC 202 and the optical modulator chip 203 are connected by a wiring board 215 having a substantially linear high frequency line and pillars/bumps 216 and 217. However, in consideration of a case where the PAD pitches are different, and the like, it is allowable to have a gentle curvature to such an extent that significant characteristic deterioration does not occur for the high frequency line.

One of the differences between the optical transmitter 200 according to the present disclosure and the optical transmitter 100 according to the related art resides in the mounting form of the driver IC. As illustrated in FIG. 2, in the optical transmitter 200 according to the present disclosure, the driver IC 202 is mounted on the subcarrier 204, similar to the optical modulator chip 203 and the lenses 212 and 213. As described above, since the subcarrier 204 is installed on the Peltier device 205, temperature control by the Peltier device 205 also extends to the driver IC 202 in the optical transmitter 200. Therefore, in the optical transmitter 200, similarly to the optical modulator chip 203, the driver IC 202 can also manage the temperature.

When considering a specific temperature, for example, in a case where the optical modulator chip 203 is an InP modulator, the optical modulator chip 203 is often used at about 45±10 °C because modulation efficiency decreases when the temperature is excessively low (however, depending on the semiconductor element design, there are modulator chips used at lower temperatures). On the other hand, it is known that the driver IC 202 has better high frequency band characteristics at a lower temperature. Thus, the Peltier device 205 needs to be controlled to be constant at any temperature in the range of 25 to 50 °C so that the characteristic of the optical modulator chip 203 is not significantly deteriorated and the characteristic of the driver IC 202 can be sufficiently extracted.

In FIG. 2, the subcarrier 204 is mounted between the Peltier device 205 and the driver IC 202, the optical modulator chip 203, and the optical member (for example, the lenses 212 and 213, and the like). The subcarrier 204 adjusts heights of the driver IC 202 and the optical modulator chip 203 to be described later, and functions as a substrate for extracting DC wiring of the driver IC 202 and the optical modulator chip 203. As the subcarrier 204, for example, a material having excellent thermal conductivity such as aluminum nitride (AlN) is desirably used. In addition, since AlN has a linear expansion coefficient close to that of InP applied to the optical modulator chip 203, and can suppress thermal stress generated in the vicinity of the interface with the InP modulator, AlN is suitable as a material applied to the subcarrier 204. Note that, on the subcarrier 204, wiring (not illustrated) for taking out the DC wiring of the optical modulator chip 203, a positioning marker (not illustrated) for mounting an optical member (for example, the lenses 212 and 213, and the like), and the like are formed by a metal pattern.

In addition, for reasons similar to the above, it is desirable that AlN is also applied to an upper surface portion of the Peltier device 205 (portion in contact with the subcarrier 204).

Note that the subcarrier 204 is depicted as a single layer in FIG. 2, but may be a multilayer. In particular, in a case where the number of DC wirings is large, or in a case where it is necessary to switch the order of terminals, it is possible to perform a layout using multilayer wirings by forming a multilayer.

The subcarrier 204 and the driver IC 202, and the subcarrier 204 and the optical modulator chip 203 need to be mounted with a conductive paste or solder having a thermal conductivity of 30 W/mK or more in order to efficiently perform heat dissipation in the Peltier device 205. From the viewpoint of management of the process temperature and the like at the time of mounting, it is desirable to use all the same conductive pastes or solders, but these bonding fillers are not necessarily the same and it is also possible to use a combination of bonding fillers having different fixing temperatures and the like.

In addition, the optical member such as the lenses 212 and 213 is desirably mounted on the subcarrier 204 similarly to the driver IC 202 and the optical modulator chip 203 in order not to cause thickness variation or the like of the adhesive due to temperature change. With such a configuration, it is possible to minimize fluctuation of an optical insertion loss due to a temperature change and the like.

### Configuration of Part Contributing to High Frequency Mounting

Next, a configuration of a part contributing to high frequency mounting will be described. When the inductance of the connection portion between the driver IC 202 and the optical modulator chip 203 increases, roll-off in the high frequency characteristic shifts to the low frequency side due to LC resonance. Thus, in order to achieve the broadband HB-CDM, it is desirable to reduce the inductance between the driver IC 202 and the optical modulator chip 203. Thus, in the optical transmitter 200 according to the present disclosure, a configuration is employed in which the wiring board 215 is flip-chip mounted face down between the driver IC 202 and the optical modulator chip 203, and the driver IC 202 and the wiring layer 209 are connected by the gold wire line 210.

The driver IC 202 and the optical modulator chip 203 are connected via the wiring board 215 and the pillars/bumps 216 and 217. The wiring board 215 and the pillars/bumps 216 and 217 may be formed by face down flip-chip mounting, and the pillars/bumps 216 and 217 may be Au pillars/bumps or Cu pillars/bumps. In order to perform stable mounting on the connection portion between the driver IC 202 and the optical modulator chip 203 having such a configuration, it is desirable that heights of respective upper surfaces (surfaces on which the pillars/bumps are mounted) of the driver IC 202 and the optical modulator chip 203 coincide with each other, and the wiring board 215 is mounted so as to have high parallelism with respect to the driver IC 202 and the optical modulator chip 203. Specifically, when the inclination of the wiring board 215 with respect to the driver IC 202 and the optical modulator chip 203 exceeds ±3°, a bonding failure such as generation of a gap in the joint portion may occur. In addition, since a stress concentration portion may be generated in the joint portion accordingly, there is a possibility that the joint portion is brittle against vibration impact and causes destruction of the joint portion, and as a result, long-term reliability of the device cannot be ensured. Thus, at the time of mounting, it is necessary to perform management in such a manner that the inclination in the height direction of the wiring board 215 with respect to main surfaces of the driver IC 202 and the optical modulator chip 203 is within ±3° and the heights of the upper surfaces of the driver IC and the optical modulator chip 203 coincide with each other.

The dimensions of an Au pillar/bump or a Cu pillar/bump generally used as the pillars/bumps 216 and 217 are often equal to or less than 100 um in both diameter and height. Thus, the height difference between the driver IC 202 and the upper surface of the optical modulator chip 203 is desirably managed to be equal to or less than at least 100 um (ideally equal to or less than 50 um).

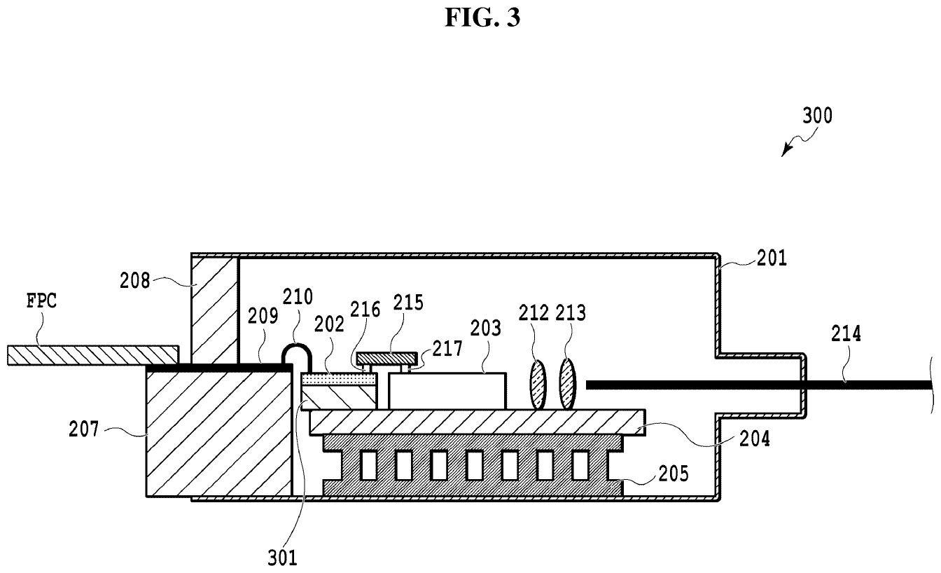

As described above, the heights of the upper surface of the driver IC 202 and the optical modulator chip 203 need to coincide with each other (at least, the height difference is equal to or less than 100 μm). From the viewpoint of minimizing the variation in the height difference, it is most desirable that the driver IC 202 and the optical modulator chip 203 having the same chip thickness are mounted on the same subcarrier 204 as illustrated in FIG. 2 (for example, the driver IC 202 and the optical modulator chip 203 have the same thickness of 300 μm). On the other hand, as illustrated in FIG. 3, it is also assumed that the driver IC 202 and the optical modulator chip 203 have different thicknesses (for example, a case where the thickness of the driver IC 202 is 100 μm and the thickness of each of the optical modulator chips 203 is 300 μm, or the like). In such a case, as illustrated in FIG. 3, by mounting the driver IC 202 and the optical modulator chip 203 on separate members, the heights of the respective upper surfaces can be adjusted to coincide with each other (FIG. 3 illustrates, as an example, a mode in which only the driver IC 202 is mounted via the metal block 301 as the member). As the block 301, a metal such as CuW or a ceramic having excellent thermal conductivity such as AlN can be applied in consideration of a heat dissipation property and stability of GND of the driver IC 202.

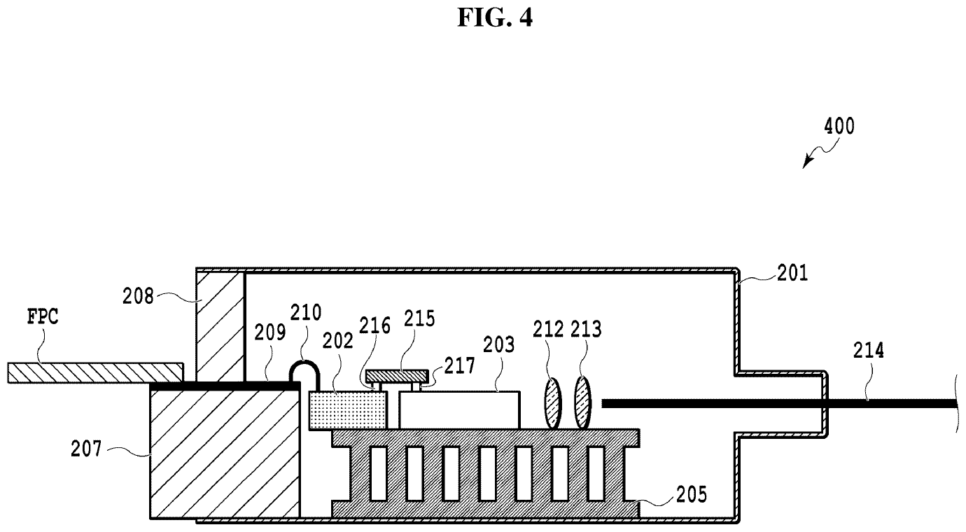

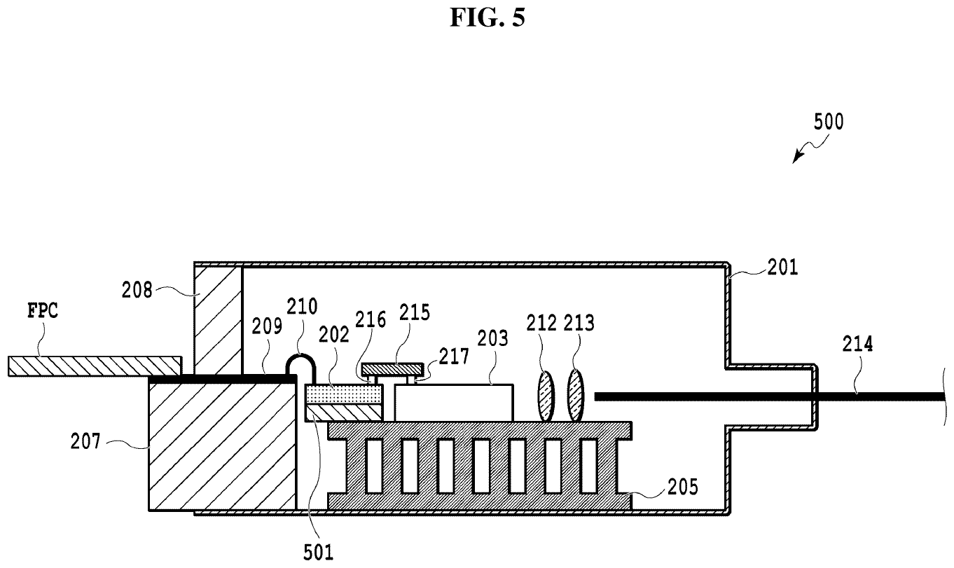

In FIG. 2, the driver IC 202 and the optical modulator chip 203 are illustrated as being mounted on the same subcarrier 204, but may be mounted on the Peltier device 205 as illustrated in FIGS. 4 and 5. In particular, as illustrated in FIG. 4, when the thicknesses of the driver IC 202 and the optical modulator chip 203 coincide with each other, if AlN having DC wiring and an alignment mark for optical mounting is applied to the upper surface of the Peltier device 205 (surface on which the driver IC 202 and the optical modulator chip 203 are mounted), the number of components can be reduced. Such a reduction in the number of components leads to a reduction in thermal resistance, which is suitable from the viewpoint of temperature control. On the other hand, as illustrated in FIG. 5, even in a case where the thicknesses of the driver IC 202 and the optical modulator chip 203 are different from each other, a similar effect can be obtained by making the heights of the driver IC 202 and the optical modulator chip 203 coincide with each other using a metal block 501 for height adjustment.

Further, considering the heat inflow from the driver IC 202, the distance between the driver IC 202 and the optical modulator chip 203 is desirably equal to or more than 300 μm. On the other hand, in consideration of deterioration in joining strength and high frequency characteristics, the length of the wiring board 215 is desirably equal to or less than 2 mm at the longest.

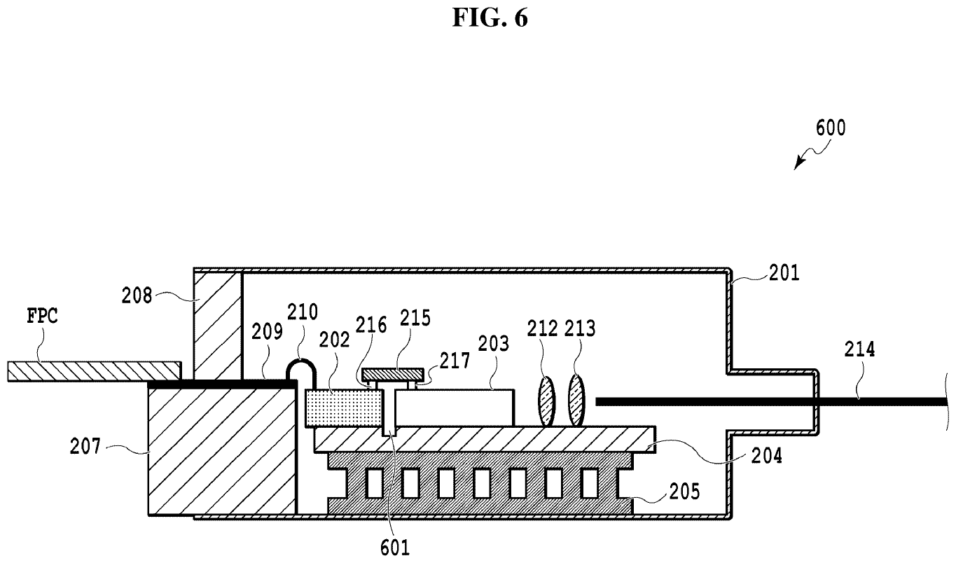

In addition, in the case of the mode including the subcarrier 204 as illustrated in FIGS. 2 and 3, as in the optical transmitter 600 illustrated in FIG. 6, a thermal separation groove 401 formed between the driver IC 202 and the chip 203 of the optical modulator and in at least one of an upper surface or a lower surface of the subcarrier 204 may be further included (FIG. 6 illustrates a form formed in the upper surface as an example). With such a configuration, it is possible to thermally separate the driver IC 203 and the modulator chip 204.

In a case where the optical modulator chip 203 is an InP modulator, while the wiring board 215 is preferably AlN from the viewpoint of a difference in linear expansion coefficient from InP, from the viewpoint of further suppressing heat inflow from the driver IC 202, it is desirable to use a material having low thermal conductivity such as SiO₂ or a resin using another dielectric material. The material applied to the wiring board 215 as described above is preferably appropriately selected according to design, and is not necessarily limited to the above materials. For example, even ceramics such as alumina other than AlN can provide a similar effect.

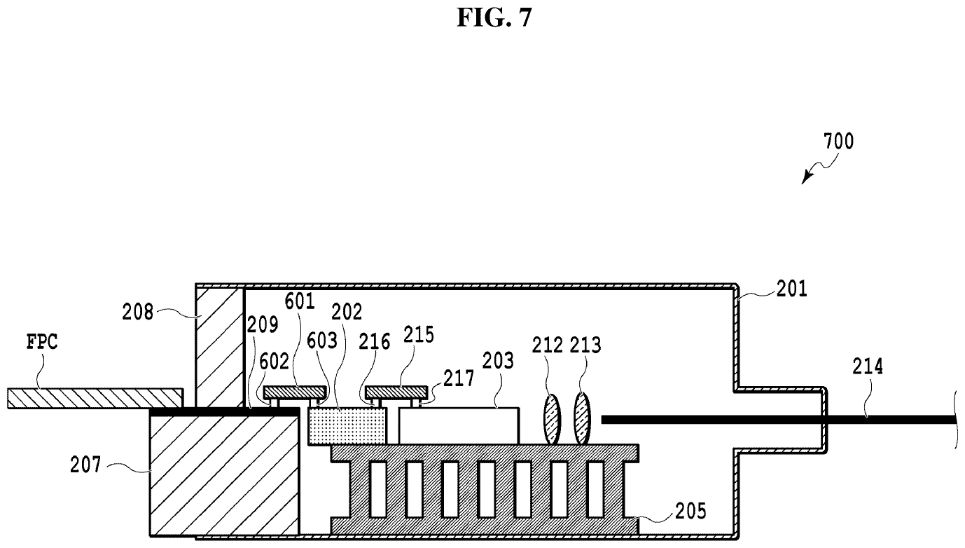

Furthermore, in FIGS. 2 to 5, while only the driver IC 202 and the optical modulator chip 203 are illustrated to be connected via the wiring board 215, as illustrated in FIG. 7, the driver IC 202 and the wiring layer 209 may also be connected by flip-chip mounting using the wiring board 601 and the pillars/bumps 602 and 603 instead of the gold wire line 210. Even in such a case, for reasons similar to the above-described height difference between the driver IC 202 and the optical modulator chip 203 and the inclination of the wiring board 215, the height difference between the upper surface of each of the driver IC 202 and the wiring layer 209 needs to be equal to or less than at least 100 μm (ideally equal to or less than 50 μm), and the inclination of the wiring board 601 with respect to the driver IC 202 and the wiring layer 209 needs to be within ±3°. The materials of the wiring board 601 and the pillars/bumps 602 and 603 may be the same as or different from those of the wiring board 215 and the pillars/bumps 216 and 217, but are desirably the same from the viewpoint of cost. In such a case, the input/output PAD of the driver IC is made the same, and the PAD shapes, pitches, and the like of the connection portions between the optical modulator chip 203 and the wiring layer 209 are made the same, so that the cost can be reduced using the same wiring board.

In addition, from the viewpoint of high frequency characteristics, in order to most efficiently utilize the characteristics of the driver IC 202, it is desirable that the driver IC 202 and the optical modulator chip 203 have a differential line configuration. In addition, when the high frequency differential line has a curvature, characteristics are greatly deteriorated, and thus it is desirable that the high frequency line on the wiring board is formed as a straight line. In order to form a straight line, it is desirable that the connection PAD pitches of the respective members coincide with each other.

Note that, as illustrated in FIGS. 2 to 5, when the driver IC 201 and the wiring layer 209 are connected by the gold wire line 210, the height difference between the driver IC 201 and the upper surface of the wiring layer 209 is desirably about 100 μm. When the gold wire line 210 is a ball wire, from the viewpoint of minimizing the wire length, it is preferable that the height of the upper surface of the driver IC 202 is set lower than the height of the upper surface of the wiring layer 209, and the gold wire line 210 is drawn up from the driver IC 202 toward the wiring layer 209. On the other hand, when the gold wire line 210 is a wire that does not have a loop and can connect the driver IC 201 and the wiring layer 209 in a flat manner, it is desirable that the heights of the driver IC 201 and the upper surface of the wiring layer 209 coincide with each other.

In addition, in FIGS. 2 to 6, the optical member is assumed to be mounted with a lens but is not limited thereto, and a member other than the lens may be applied. In addition to the lenses 212 and 213, the optical member includes a fiber fixing member and the like.

### Configuration of Peltier Device

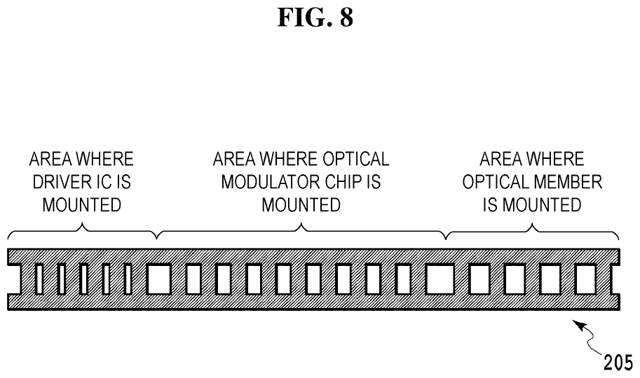

FIG. 8 is a diagram illustrating a configuration of the Peltier device 205 used in the optical transmitter (optical transmitters 200 to 700) according to the present disclosure. In the optical transmitter according to the present disclosure, since there is a difference in the calorific value between the driver IC 202 and the optical modulator chip 203, when considering the temperature distribution of each element, the temperature of the driver IC 202 is the highest, and then the optical modulator chip 203 and then the optical member (for example, the lenses 212 and 213, and the like) are in this order. When the element density of the n-type and p-type semiconductors constituting the Peltier device 205 is made constant in a state where the temperature distribution is generated as described above, a state may occur in which the area where the optical member is mounted is excessively cooled or the area where the driver IC 202 is mounted is not sufficiently cooled. Thus, it is desirable that the element density of the n-type and p-type semiconductors constituting the Peltier device 205 is changed according to the temperature distribution. As illustrated in FIG. 8, in an example of the Peltier device 205 used in the optical transmitter according to the present disclosure, element densities of n-type and p-type semiconductors are configured in such a manner as to satisfy the area where the driver IC 202 is mounted>the area where the optical modulator chip 203 is mounted>the area where the optical member is mounted. With such a configuration, it is possible to perform appropriate temperature control (suppression of excessive cooling or insufficient cooling) according to the temperature distribution.

### Industrial Applicability

As described above, an optical transmitter according to the present disclosure can achieve a novel configuration and mounting form of an optical transmitter that suppresses temperature dependency of an optical transmitter including a driver IC, has excellent speed, and can stably operate regardless of environmental temperature. Thus, application to a high-speed digital coherent optical transmission system or the like is expected.

1. An optical transmitter comprising:
an optical modulator chip;
a driver IC for operating the optical modulator chip;
a wiring board that has a substantially linear high frequency line, connects the optical modulator chip and the driver IC, and is face-down mounted by flip-chip mounting; and
a Peltier device mounted below the optical modulator chip and the driver IC, wherein
the optical modulator chip and the driver IC are temperature-controlled by the Peltier device that is the same.

2. The optical transmitter according to claim 1, wherein
a height difference between upper surfaces of the optical modulator chip and the driver IC is equal to or less than 100 μm, and
an inclination in a height direction of a main surface of the wiring board with respect to a main surface of the optical modulator chip and a main surface of the driver IC is within ±3°.

3. The optical transmitter according to claim 1, wherein a distance between the optical modulator chip and the driver IC is equal to or more than 300 μm and equal to or less than 2 mm.

4. The optical transmitter according to claim 1, wherein the temperature of the Peltier device is controlled to be constant at any temperature in a range of 25 to 50 °C.

5. The optical transmitter according to claim 1, wherein
a material of an upper surface of the Peltier device is aluminum nitride (AlN),
the optical modulator chip is an indium phosphide (InP) optical modulator chip, and
the Peltier device is connected to the optical modulator chip and the driver IC by a conductive paste or solder having a thermal conductivity of 30 W/m K or more.

6. The optical transmitter according to claim 1, further comprising
an optical member that temperature is controlled by the Peltier device, wherein
element densities of n-type and p-type semiconductors constituting the Peltier device are set such that an area that the driver IC is mounted, an area that the optical modulator chip is mounted, a mounting area of the optical member are in descent order.

7. The optical transmitter according to claim 1, further comprising a subcarrier between the Peltier device and the optical modulator chip and the driver IC.

8. The optical transmitter according to claim 7, further comprising a thermal separation groove on at least one of an upper surface or a lower surface of the subcarrier between the driver IC and the optical modulator chip.

9. The optical transmitter according to claim 1, wherein
the optical modulator chip and the driver IC are mounted in a housing in a HB-CDM form, and
the optical modulator chip and the driver IC have a differential line configuration.
